(19) United States
(12) Patent Application Publication
(10) Pub. No.: US 2026/0115821 A1
(43) Pub. Date: Apr. 30, 2026

(54) Method and Device for Machining a Wafer-Holding Device for a Wafer Lithography Process

(71) Applicant: ASML Netherlands B.V., Veldhoven (NL)

(72) Inventor: Constans Mathias WEBER, Berlin (DE)

(73) Assignee: ASML Netherlands B.V., Veldhoven (NL)

(21) Appl. No.: 18/025,851

(22) PCT Filed: Aug. 26, 2021
(86) PCT No.: PCT/EP2021/073640

§ 371 Date: Oct. 30, 2024

(30) Foreign Application Priority Data
Sep. 10, 2020 (DE) 10 2020 123 660.3

(51) Int. Cl. B23H 3/00; G03F 7/00

(52) U.S. Cl. CPC B23H 3/00; G03F 7/707; G03F 7/7095; G03F 7/70991

(57) ABSTRACT

A method for machining a wafer-holding device 10 for a wafer lithography process, such as e.g. immersion lithography or lithography under vacuum conditions, the wafer-holding device 10 comprising a carrier body 11 having an electrically conductive diamond cover layer 12. An electrochemical cell 20 is formed on the wafer-holding device 10 by the diamond cover layer 12, a counter electrode 21, an electrolyte liquid 22 in a gap between the diamond cover layer 12 and the counter electrode 21, and a voltage source 23 which is electrically connected to the diamond cover layer 12 and the counter electrode 21. Material is removed electrochemically on the wafer-holding device by means of the electrochemical cell 20. A surface machining device 200 is also described which is designed to machine a wafer-holding device 10 for a wafer lithography process.

The invention relates to a method for machining a wafer holding device for a wafer lithography process, the wafer holding device comprising a carrier body having an electrically conductive diamond cover layer. The invention furthermore relates to a surface machining device, which is configured to machine a wafer holding device for a wafer lithography process. Applications of the invention lie in the production and machining, in particular cleaning of wafer holding devices for lithographic methods, such as e.g., immersion lithography or lithography under vacuum conditions.

Reference is made in the present description to the following prior art which represents the technical background of the invention:
[1] WO 2018/007498 A1:
[2] WO 2019/0115195 A1:
[3] O. Debus “Auf die harte Tour-Vollständige Oxidation von Abwasserschadstoffen mit Diamantelektroden” in “CHEMIE TECHNIK” No. 6 2004 (Volume 33):
[4] A. Kraft “Doped Diamond: A Compact Review on a New, Versatile Electrode Material” in “Int. J. Electrochem. Sci.” 2 (2007) 355-385; and
[5] B. Marselli et al. “Electrogeneration of Hydroxyl Radicals on Boron-Doped Diamond Electrodes” in “Journal of The Electrochemical Society” 150 (3), March 2003.

Immersion lithography is generally known as a lithographic technique for structuring surfaces, e.g., in wafer structuring. The wafer surface is exposed to light using an exposure apparatus and an immersion liquid which enables, in the case of a given wavelength, an enlarged numerical aperture and thus the production of smaller structures. The wafer is arranged for exposure to light on a wafer holding device which comprises a carrier body with projections (burls), the front sides of which span a carrier surface for accommodating the wafer.

The carrier surface, formed by the front sides of the burls, of a wafer holding device for the lithography should have as low as possible a coefficient of friction and a high degree of evenness which is as permanent as possible. Both requirements can be satisfied by hard material coatings, such as, e.g., by a DLC (diamond-like carbon) layer or a diamond layer (see e.g. [1] or [2]). However, abrasive and/or corrosive wear to the carrier surface can occur over the course of the operating period. The abrasive wear is caused by mechanical contact of carrier surface and wafer, while the corrosive wear is brought about especially in the case of immersion lithography by the immersion liquid. As a result of the wear, the desired properties in terms of friction and evenness can be lost and surface ‘contamination can occur. This contamination also has a negative effect on the stated properties since, as a result of the build-up of material, evenness is lost and the friction properties are potentially only determined by the contamination.

It is known from the practice of the use of wafer holding devices to remove contamination mechanically with what is known as a whetstone. Cleaning with the whetstone has, however, disadvantages since it does not entirely eliminate contamination and can cause mechanical damage to the wafer holding device.

It is furthermore known from another technical field to use boron-doped diamond layers on electrodes (what are known as diamond electrodes) for electrochemical water cleaning (see e.g. [3] to [5]). The water to be cleaned is arranged as an electrolyte liquid between the diamond electrodes, as a result of which an electrochemical cell is formed. In the event of an electrical voltage acting upon the diamond electrodes, the water is split, and OH radicals are formed on the surfaces of the diamond electrodes. The high oxidation potential of the radicals ensures efficient depletion in particular of organic compounds in the water.

The object of the invention is to provide an improved method for machining a wafer holding device for the lithography process and an improved surface machining device for machining a wafer holding device for the lithography process, with which disadvantages of conventional technologies are avoided. It should be possible to remove contamination, in particular residues of lithography coatings, as easily as possible with the method and the surface machining device, in particular inside and/or outside a lithography machine. The elimination of contamination should furthermore be enabled with improved reliability and without the risk of undesirable damage to the wafer holding device.

This object is achieved by a method for machining a wafer holding device for the immersion lithography process or by the surface machining device with the features of the independent claims. Advantageous embodiments and applications of the invention will become apparent from the dependent claims.

According to a first general perspective of the invention, the above object is achieved by a method for machining a wafer holding device for a wafer lithography process, the wafer holding device comprising a carrier body having an electrically conductive diamond cover layer. According to the invention, an electrochemical cell is formed on the wafer holding device by the diamond cover layer, a counter electrode, an electrolyte liquid in a gap between the diamond cover layer and the counter electrode, and a voltage source which is electrically connected to the diamond cover layer and the counter electrode. Moreover, according to the invention, material is removed electrochemically on the wafer holding device by means of the electrochemical cell.

According to a second general perspective of the invention, the above object is achieved by a surface machining device which is designed to machine a wafer holding device for a wafer lithography process, and which comprises the wafer holding device, comprising a carrier body having an electrically conductive diamond cover layer, a counter electrode, which is arranged at a distance from the wafer holding device, which is formed to accommodate an electrolyte liquid, and a voltage source, which is arranged for acting upon the diamond cover layer with an electrical operating voltage relative to the counter electrode. An electrochemical cell, which is designed for electrochemical removal of material on the wafer holding device, is formed by the diamond cover layer, the counter electrode, the electrolyte liquid in the gap between the diamond cover layer and the counter electrode, and the voltage source. The surface machining device is preferably configured to carry out the method according to the first general perspective of the invention or one of its embodiments. The wafer holding device, in particular its diamond cover layer, is part of the surface machining device for machining the wafer holding device.

The invention exploits the suitability of doped diamond which is arranged on the surface of the wafer holding device, in particular on the burls, to provide an electrode of an electrochemical cell. The diamond cover layer is used as a cleaning electrode. The inventors have ascertained that the generation of radicals during operation of the electrochemical cell, as is known from conventional water treatment, can be exploited in order to deplete contaminants on the surface of the wafer holding device under the action of the radicals. In contrast to water treatment, in the case of the machining according to the invention of the wafer holding device, the contaminants are not contained in the electrolyte liquid of the electrochemical cell, but rather are present on the surface of the wafer holding device.

The coating of the surface of the wafer holding device with diamond advantageously satisfies a multiple function. Firstly, a low degree of friction and a high degree of mechanical durability of the surface during operation of the wafer holding device are provided by the diamond cover layer. Secondly, diamond represents a particularly advantageous electrode material since diamond enables the electrochemical cell to be acted upon with such a high operating voltage that the water in the electrolyte liquid is split and the desired OH radicals are generated.

As a result of the invention, the wafer holding device can be equipped with a self-cleaning function which makes it possible to eliminate contamination in an active and targeted manner. In-situ application of the invention is possible, hence standstill times of a lithography machine are advantageously minimized.

The term “wafer holding device” refers to all wafer holders or carriers which are suitable for lithography. The carrier body of the wafer holding device is typically a flat panel with a structured surface on which burls to accommodate a wafer are arranged. The carrier body can be electrically conductive or electrically insulating. In the preferred case of an electrically conductive carrier body, it is sufficient if the electrically conductive diamond cover layer is composed of a plurality of separate cover layer portions which are arranged in each case on the front faces of the burls. The entirety of the cover layer portions forms the diamond cover layer. The acting upon of the cover layer portions with the operating voltage of the electrochemical cell is performed via the carrier body. In the alternative case of an electrically non-conductive carrier body, the electrically conductive diamond cover layer is preferably provided as an exposed coherent layer, particularly preferably as a seamless, closed layer on the structured surface, in so far as this surface accommodates the wafer, and is electrically connected to the voltage source. Optionally, the electrically conductive diamond cover layer can comprise multiple diamond cover layer portions on the structured surface which are formed in each case as exposed coherent layers, particularly preferably as seamless, closed layers and are connected electrically to one another and/or to the voltage source.

The electrochemical cell (or electrolysis cell), which is formed by the diamond cover layer and the counter electrode and the electrolyte liquid between these, is configured, in the event of an electrical voltage acting upon the diamond cover layer and the counter electrode, to generate OH radicals in the electrolyte liquid. For this purpose, the electrolyte liquid contains water. The spacing between the counter electrode and the diamond cover layer is preferably selected in the range of less than 5 mm. The electrolyte liquid is preferably composed of ultrapure water (water which contains no or a negligible amount of foreign substances). The use of ultrapure water has particular advantages as an immersion liquid and in the minimisation of undesirable electrochemical reactions.

The OH radicals bring about a removal of material on the surfaces which adjoin the electrolyte liquid. i.e., in particular on the diamond cover layer. The magnitude and speed of the removal of material is determined by operating parameters of the electrochemical cell, in particular the voltage applied and the duration of the action of the voltage on the cell. The operating parameters of the electrochemical cell are selected by the person skilled in the art as a function of the concrete conditions of use, in particular using tests or reference values. The voltage between the diamond cover layer and the counter electrode is selected so that free OH radicals are formed in the electrochemical cell, and it is preferably at least 2.2 V, particularly preferably at least 2.4 V.

According to one preferred embodiment of the invention, the removal of material comprises an electrochemical decomposition of foreign substances on the surface of the wafer holding device. The electrochemical cell is designed for electrochemical decomposition of foreign substances on the surface of the wafer holding device. The decomposition of foreign substances on the surface comprises a detachment of foreign substances adhering to the surface and/or chemical conversion of the foreign substances through the action of the OH radicals. Operating parameters of the electrochemical cell, in particular the applied voltage and the duration of the action of the voltage on the cell, can advantageously be selected such that the foreign substances are reactively decomposed, but the surface of the wafer holding device remains unchanged (or only has a negligibly small reaction with the OH radicals).

The foreign substances comprise any substances, which are not part of the wafer or the wafer holding device. The foreign substances particularly preferably comprise residues of a lithography coating. The foreign substances detached from the surface and/or the reaction products of the decomposition of the foreign substances with the electrolyte fluid are furthermore preferably flushed from the surface of the wafer holding device. The electrolyte liquid is advantageously replaced during machining so that contaminants are transported away.

According to a further preferred variant of the invention, the removal of material comprises electrochemical decomposition of diamond on the surface of the diamond cover layer. In the case of this embodiment, the electrochemical cell is designed for electrochemical decomposition of diamond on the surface of the diamond cover layer. The inventors have ascertained that the electrochemical reaction can additionally be used to deplete diamond from the diamond cover layer in a targeted manner and correct its evenness. The operating parameters of the electrochemical cell are adjusted so that diamond can be electrochemically decomposed and carbon can be removed. A removal of up to a few nanometres is advantageously possible. The electrochemical cell can advantageously be operated reproducibly in such a manner that uncontrolled damage to the diamond cover layer is ruled out.

The diamond cover layer can advantageously undergo evenness correction and/or roughening through the electrochemical machining. The electrochemical decomposition of diamond on the surface of the diamond cover layer brings about a correction of the thickness of the diamond cover layer and thus the height of the burls and/or a targeted setting of the roughness, such as, e.g., a tribologically useful roughening in particular of the front faces of the burls. A wafer holding device for immersion lithography with an intrinsic cleaning function and with an ability to correct the evenness of the carrier surface spanned by the burls is advantageously created with this embodiment of the invention.

It may be advantageous in particular for the removal of material from the diamond cover layer to locally selectively adjust the removal of material. The removal of material can be adjusted as a function of the position on the surface of the wafer holding device. For this purpose, according to a further variant of the invention, the counter electrode is dimensioned and arranged such that the electrochemical cell is formed with a sub-region of the diamond cover layer and a local restricted removal of material is performed. The counter electrode preferably extends over the sub-region of the diamond cover layer and the electrochemical cell is designed for locally restricted removal of material. The adjustment of the size of the counter electrode can advantageously be combined with a small-scale guidance of the electrolyte liquid, as a result of which the delimitation of the electrochemical cell from the surroundings and the selectivity of the local treatment are improved. The locally selective adjustment of the removal of material can comprise in particular a restriction of the generation of the OH radicals to a group of burls or even to a single burl. This advantageously enables a local correction and/or a targeted local adjustment of the roughness, such as, e.g., tribologically useful roughening.

According to one particularly advantageous variant of the invention, the counter electrode can be moved parallel to the diamond cover layer and the removal of material can be performed in different sub-regions of the diamond cover layer with different reaction conditions. In relation to the device, for this purpose, the counter electrode is arranged movably parallel to the diamond cover layer and the electrochemical cell, in particular a control of the voltage source, can be designed so that the removal of material is performed in different sub-regions of the diamond cover layer with different reaction conditions. For example, a control of the voltage source can be provided in such a manner that the operating parameters of the electrochemical cell are varied as a function of the mutual positioning of the counter electrode and the diamond cover layer in order to achieve a predetermined position-dependent removal of material.

Wafer holding devices with the electrochemical machining according to the invention advantageously achieve a new function. The electrolyte liquid required for operation of the electrochemical cell is preferably provided by the immersion liquid during operation of an immersion lithography machine. The machining of the wafer holding device is correspondingly preferably performed in situ in an immersion lithography machine. The surface machining device is, in the case of this variant of the invention, preferably a part of an immersion lithography machine. Alternatively, the machining of the surface of the wafer holding device can be performed in a separate structure outside the lithography machine.

According to further preferred embodiments of the invention, the counter electrode can be connected to an exposure lens, which points towards the wafer holding device, of the immersion lithography machine and/or have a diamond surface. The immersion liquid which provides the electrolyte liquid is arranged between the exposure lens and the diamond cover layer. In particular, local machining of the wafer holding device is advantageously facilitated by the coupling of the counter electrode to the exposure lens. The use of the counter electrode with a diamond surface (diamond electrode) has particular advantages in terms of the voltage which can be applied to the electrochemical cell and the avoidance of contamination on the counter electrode.

Further details and advantages of the invention will be described below with reference to the enclosed drawing. In the drawing:

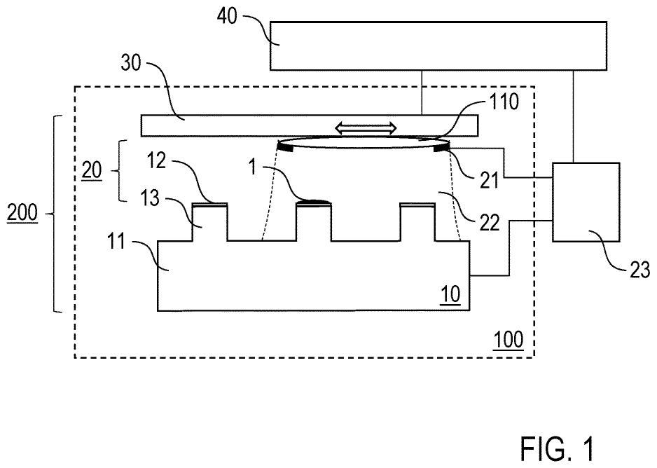

FIG. 1: schematically shows features of embodiments of the method according to the invention and the surface machining device according to the invention.

It is emphasised here that features of embodiments of the invention are schematically illustrated in FIG. 1. For the sake of clarity, individual parts are not represented true-to-scale. By way of example, reference is made to machining of a wafer holding device for immersion lithography. The invention is not restricted to this application, but rather can be used correspondingly in the machining of a wafer holding device (EUV chuck) for lithography in a vacuum. Details of the respective lithography method and the design of a wafer holding device are not described insofar as these are known per se from the prior art.

Embodiments of the invention are described below in particular with exemplary reference to the provision of a surface machining device as part of a lithography machine, wherein a counter electrode of an electrochemical cell is coupled to an exposure lens of the lithography machine. It is emphasised that the implementation of the invention in practice is not restricted to this variant. On the contrary, modifications are in particular possible in that the counter electrode is provided independently of the exposure lens and/or the surface machining device is arranged and operated outside the lithography machine.

FIG. 1 schematically shows the lithography machine 100, comprising a wafer holding device 10, an exposure lens 110 and an actuating apparatus 30 to adjust the exposure lens 110 relative to the wafer holding device 10. Further parts of the lithography machine 100, such as, for example, a light source and a projection system for the exposure, tools for placing wafers on the wafer holding device 10 and a control unit of the lithography machine 100, are not represented in FIG. 1.

The wafer holding device 10 comprises a carrier body 11, the structured surface of which is formed by a plurality of protruding burls 13. In practice, the carrier body 11 has, for example, a diameter of 30 cm and several thousand burls 13 in each case with a diameter of less than one mm. The carrier body 11 is composed, for example, of silicon-infiltrated silicon carbide (SiSiC) which possesses inherent electrical conductivity. Planar front faces of the burls 13 span a carrier surface to accommodate a wafer (not represented).

A diamond cover layer 12 which comprises a plurality of diamond cover layer portions in each case on the planar front faces of the burls 13 is provided on the surface of the carrier body 11. The diamond cover layer 12 has a thickness of 0.5 μm to 20 μm and it is composed of boron-doped diamond (boron concentration, e.g., 4000 ppm). The diamond cover layer 12 is produced, for example, by carbon separation by means of CVD using methane and hydrogen in the presence of gas which contains boron.

The surface machining device 200 is, in the case of the example shown, part of the lithography machine 100. The electrochemical cell 20 of the surface machining device 200 is formed by the diamond cover layer 12, in particular the diamond cover layer portions moistened by the electrolyte liquid 22, and the counter electrode 21. On one hand, the diamond cover layer 12 and, on the other hand, the counter electrode 21 are electrically connected to a voltage source 23 to provide an operating voltage of the electrochemical cell 20. The voltage source 23 is, for example, a variable source with a controllable output voltage of up to 3 V.

The counter electrode 21 comprises, for example, an annular electrode layer composed of boron-doped diamond which is arranged on the side of the exposure lens 110 pointing towards the wafer holding device 10. The thickness of the diamond layer or the counter electrode 21 is, for example, 8 μm. The distance between the counter electrode and the front faces of the burls 13 is, e.g., 1 mm.

The exposure lens 110 and the counter electrode 21 are coupled to the actuating apparatus 30 with which the exposure lens 110 and the counter electrode 21 can be positioned relative to the wafer holding device 10. The actuating apparatus 30 comprises, for example, an x-y-translation drive which is designed for a displacement parallel to the surface of the carrier body 11.

The actuating apparatus 30 and the voltage source 23 are coupled to a control apparatus 40. The control apparatus 40, which comprises, for example, a computer circuit, is designed to actuate the voltage source 23 in accordance with predetermined operating parameters of the electrochemical machining of the surface of the carrier body 11 and the actuating apparatus 30 for positioning the exposure lens 110 and the counter electrode 21. For example, it can be provided to adjust the operating parameters, in particular the voltage and the duration of the action of the voltage on the counter electrode 21, as a function of the position relative to the surface of the wafer holding device 10.

In contrast to FIG. 1, the counter electrode 21 can also be provided on a cleaning head separated from the exposure lens 110, which cleaning head can be moved with the actuating apparatus 30 or an alternative drive. According to a further modification, in contrast to FIG. 1, the counter electrode 21 can extend superficially parallel to the surface of the wafer holding device 10 and so as to cover the arrangement of all the burls.

The inherently known process of immersion lithography, comprising placing a wafer on the burls 13, exposing the wafer to light through the immersion liquid and subsequent processing of the wafer exposed to light, is performed during operation of the lithography machine 100. As a result of the handling of the wafer in practical production conditions, contamination 1 arises which is formed, for example, by residues of lithography coatings on individual or all burls 13.

In order to eliminate the contamination 1, the immersion liquid is provided as electrolyte liquid 22 between the surface of the carrier body 11 and the counter electrode 21. By acting upon the diamond cover layer 12 and the counter electrode 21 with the voltage of the voltage source 23, OH radicals are formed in the electrolyte liquid 22 in accordance with

$${H}_{2} O \to •OH + {H}^{+} + {e}^{-}$$

which OH radicals bring about a detachment of the contamination 1 from the burls 13. Through the replacement of the electrolyte liquid 22, the detached contamination residues are removed from the surface of the carrier body 11.

If, e.g., during maintenance of the wafer holding device 10 with a test wafer, an unevenness of the carrier surface spanned by the burls 13 is ascertained, the unevenness can be balanced out by removal from the diamond cover layer portions with electrochemical machining. For this purpose, the operating voltage of the voltage source 23 is adjusted so that diamond is electrochemically decomposed, which makes it possible to remove diamond material.

The electrochemical machining of the surface of the wafer holding device 10 is performed on all burls 13 simultaneously or, as represented in FIG. 1, in a stepwise manner by means of a restriction to a surface portion of the carrier body 11 with a single burl or a group of burls and a subsequent displacement of the counter electrode 21 and the electrolyte liquid 22 to further burls until the entire surface of the wafer holding device 10 or a part of the surface is machined.

The features of the invention disclosed in the above description, the drawings and the claims can be significant both individually or in combination or sub-combination for the achievement of the invention in its various designs.

1. Method for machining a wafer-holding device (10) for a wafer lithography process, the wafer-holding device (10) comprising a carrier body (11) having an electrically conductive diamond cover layer (12),
characterized in that
an electrochemical cell (20) is formed on the wafer-holding device (10) by the diamond cover layer (12), a counter electrode (21), an electrolyte liquid (22) in a gap between the diamond cover layer (12) and the counter electrode (21), and a voltage source (23) which is electrically connected to the diamond cover layer (12) and the counter electrode (21), and
material is removed electrochemically on the wafer-holding device by means of the electrochemical cell (20).

2. Method according to claim 1, wherein
the removal of material comprises electrochemical decomposition of foreign substances (1) on the surface of the wafer-holding device (10).

3. Method according to claim 2, wherein
reaction products of the decomposition of the foreign substances are flushed with the electrolyte liquid from the surface of the wafer-holding device (10), and/or
the foreign substances comprise residues of a lithography coating.

4. Method according to any one of the preceding claims, wherein
the removal of material comprises electrochemical decomposition of diamond on the surface of the diamond cover layer (12).

5. Method according to claim 4, wherein
the diamond cover layer (12) undergoes roughening and/or evenness correction.

6. Method according to any one of the preceding claims, wherein
the counter electrode (21) is arranged so that the electrochemical cell (20) is formed with a sub-region of the diamond cover layer (12) and locally restricted material removal is performed.

7. Method according to claim 6, wherein
the counter electrode (21) is moved parallel to diamond cover layer (12) and the removal of material is performed in different sub-regions of the diamond cover layer (12) with different reaction conditions.

8. Method according to any one of the preceding claims, wherein
the machining of the wafer-holding device (10) is performed in situ in an immersion lithography machine (100).

9. Method according to claim 8, wherein
the counter electrode (21) is connected to an exposure lens (110), which points towards the wafer-holding device (10), of the immersion lithography machine (100).

10. Method according to any one of the preceding claims, wherein
the electrolyte liquid (22) comprises ultrapure water.

11. Surface machining device (200) which is designed to machine a wafer-holding device (10) for a wafer lithography process, comprising
the wafer-holding device (10) which comprises a carrier body (11) having an electrically conductive diamond cover layer (12),
a counter electrode (21) which is arranged at a distance from the wafer-holding device (10) which is formed to accommodate an electrolyte liquid (22), and
a voltage source (23) which is arranged to act upon the diamond cover layer (12) with an electrical operating voltage relative to the counter electrode (21), wherein
an electrochemical cell (20), which is configured for electrochemical removal of material on the wafer-holding device (10), is formed by the diamond cover layer (12), the counter electrode (21), the electrolyte liquid (22) in the gap between the diamond cover layer (12) and the counter electrode (21), and the voltage source (23).

12. Surface machining device according to claim 11, wherein
the electrochemical cell (20) is configured for electrochemical decomposition of foreign substances on the surface of the wafer-holding device (10).

13. Surface machining device according to any one of claims 11 to 12, wherein
the electrochemical cell (20) is configured for electrochemical decomposition of diamond on the surface of the diamond cover layer (12).

14. Surface machining device according to any one of claims 11 to 13, wherein
the counter electrode (21) extends over a sub-region of the diamond cover layer (12) and the electrochemical cell (20) is designed for locally restricted removal of material.

15. Surface machining device according to claim 14, wherein
the counter electrode (21) is arranged movably parallel to the diamond cover layer (12), and
the electrochemical cell (20) is configured so that the removal of material is performed in different sub-regions of the diamond cover layer (12) with different reaction conditions.

16. Surface machining device according to any one of claims 11 to 15, which is a part of an immersion lithography machine (100).

17. Surface machining device according to claim 16, wherein
the counter electrode (21) is connected to an exposure lens, which points towards the wafer-holding device (10), of the immersion lithography machine (100), and/or
the counter electrode (21) has a diamond surface.
